(19) United States
(12) Patent Application Publication
(10) Pub. No.: US 2025/0247086 A1
(43) Pub. Date: Jul. 31, 2025

(54) Continuously operating bootstrapped switch

(71) Applicant: REALTEK SEMICONDUCTOR CORPORATION, HSINCHU (TW)

(72) Inventor: SHIH-HSIUNG HUANG, Hsinchu (TW)

(21) Appl. No.: 19/011,685

(22) Filed: Jan. 7, 2025

(30) Foreign Application Priority Data
Jan. 31, 2024 (TW) 113103840

(51) Int. Cl. H03K 17/0412; H03K 17/06

(52) U.S. Cl. CPC H03K 17/04123; H03K 17/063

(57) ABSTRACT

A bootstrapped switch has an input terminal and an output terminal and includes four switches and a bootstrap capacitor switching circuit. The bootstrapped switch is turned on or off according to a clock. The bootstrap capacitor switching circuit is coupled to the four switches and includes a first capacitor and a second capacitor. When the first capacitor is charging, the second capacitor functions as a bootstrap capacitor of the bootstrapped switch, and when the second capacitor is charging, the first capacitor functions as the bootstrap capacitor of the bootstrapped switch.

### BACKGROUND OF THE INVENTION

### 1. Field of the Invention

The present invention generally relates to a bootstrapped switch, and, more particularly, to a continuously operating bootstrapped switch.

### 2. Description of Related Art

FIG. 1 is a circuit diagram of a conventional bootstrapped switch. The bootstrapped switch 100 includes a switch 101, a switch 102, a switch 103, a switch 104, a switch 105, and an N-channel metal-oxide-semiconductor field-effect transistor (N-channel MOSFET, hereinafter referred to as NMOS transistor) 106, and a bootstrap capacitor 107. The input terminal VI and the output terminal VO of the bootstrapped switch 100 are respectively coupled to the source and drain of the NMOS transistor 106. The gate of the NMOS transistor 106 is coupled to the voltage source V3 through the switch 105 as well as coupled to one terminal of the bootstrap capacitor 107 and one terminal of the switch 101 through the switch 104. The other terminal of the switch 101 is coupled to the voltage source V1. The other terminal of the bootstrap capacitor 107 is coupled to the voltage source V2 through the switch 102 and coupled to the source of the NMOS transistor 106 and the input terminal VI of the bootstrapped switch 100 through the switch 103. The voltage source V1 is a power supply voltage VDD, while the voltage source V2 and the voltage source V3 are the ground level. The operation of the bootstrapped switch 100 is known to people having ordinary skill in the art and thus omitted for brevity.

The need to charge the bootstrap capacitor 107 limits the operating frequency of the bootstrapped switch 100, which in turn reduces the performance of the overall circuit.

### SUMMARY OF THE INVENTION

In view of the issues of the prior art, an object of the present invention is to provide a bootstrapped switch, so as to make an improvement to the prior art.

According to one aspect of the present invention, a bootstrapped switch is provided. The bootstrapped switch has an input terminal and an output terminal and includes a first switch, a second switch, a third switch, a fourth switch, and a bootstrap capacitor switching circuit. The first switch has a first terminal, a second terminal, and a first control terminal. The first terminal is coupled to the input terminal, and the second terminal is coupled to the output terminal. The second switch has a third terminal, a fourth terminal, and a second control terminal. The third terminal is coupled to the input terminal, the fourth terminal is coupled to a first node, and the second control terminal is coupled to the first control terminal. The third switch has a fifth terminal, a sixth terminal, and a third control terminal. The fifth terminal is coupled to a second node, the sixth terminal is coupled to the first control terminal, and the third control terminal receives a first clock. The fourth switch has a seventh terminal, an eighth terminal, and a fourth control terminal. The seventh terminal is coupled to the first control terminal, the eighth terminal is coupled to a first reference voltage, and the fourth control terminal receives the first clock. The bootstrap capacitor switching circuit is coupled to the first node and the second node and includes a first capacitor and a second capacitor. When the first capacitor is charging, the second capacitor is coupled between the first node and the second node. When the second capacitor is charging, the first capacitor is coupled between the first node and the second node.

According to another aspect of the present invention, a bootstrapped switch is provided. The bootstrapped switch has an input terminal and an output terminal and includes a first switch, a second switch, a third switch, a fourth switch, a first capacitor, a second capacitor, and a switch group. The first switch has a first terminal, a second terminal, and a first control terminal. The first terminal is coupled to the input terminal, and the second terminal is coupled to the output terminal. The second switch has a third terminal, a fourth terminal, and a second control terminal. The third terminal is coupled to the input terminal, the fourth terminal is coupled to a first node, and the second control terminal is coupled to the first control terminal. The third switch has a fifth terminal, a sixth terminal, and a third control terminal. The fifth terminal is coupled to a second node, the sixth terminal is coupled to the first control terminal, and the third control terminal receives a first clock. The fourth switch has a seventh terminal, an eighth terminal, and a fourth control terminal. The seventh terminal is coupled to the first control terminal, the eighth terminal is coupled to a first reference voltage, and the fourth control terminal receives the first clock. The switch group is coupled to the first capacitor and the second capacitor and configured to couple the first capacitor or the second capacitor to the first node and the second node according to a second clock and a third clock.

The technical means embodied in the embodiments of the present invention can solve at least one of the problems of the prior art. Therefore, compared to the prior art, the present invention can improve the operating frequency of the bootstrapped switch.

These and other objectives of the present invention no doubt become obvious to those of ordinary skill in the art after reading the following detailed description of the preferred embodiments with reference to the various figures and drawings.

### BRIEF DESCRIPTION OF THE DRAWINGS

FIG. 1 is the circuit diagram of a conventional bootstrapped switch.

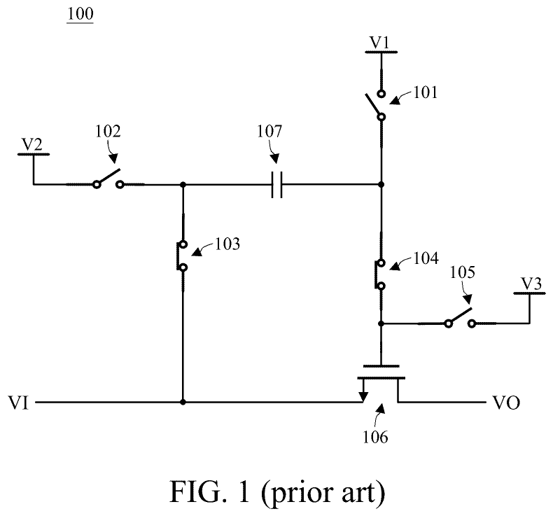

FIG. 2 is the circuit diagram of a bootstrapped switch according to an embodiment of the present invention.

FIG. 3 is the circuit diagram of a bootstrap capacitor switching circuit according to an embodiment of the present invention.

FIG. 4 shows the waveform of multiple clocks according to an embodiment of the present invention.

FIG. 5 is the circuit diagram of a bootstrapped switch according to another embodiment of the present invention.

FIG. 6 is the circuit diagram of a bootstrapped switch according to another embodiment of the present invention.

FIG. 7 is the circuit diagram of a bootstrapped switch according to another embodiment of the present invention.

### DETAILED DESCRIPTION OF THE EMBODIMENTS

The following description is written by referring to terms of this technical field. If any term is defined in this specification, such term should be interpreted accordingly. In addition, the connection between objects or events in the below-described embodiments can be direct or indirect provided that these embodiments are practicable under such connection. Said “indirect” means that an intermediate object or a physical space exists between the objects, or an intermediate event or a time interval exists between the events.

The disclosure herein includes a bootstrapped switch. On account of that some or all elements of the bootstrapped switch could be known, the detail of such elements is omitted provided that such detail has little to do with the features of this disclosure, and that this omission nowhere dissatisfies the specification and enablement requirements. A person having ordinary skill in the art can choose components or steps equivalent to those described in this specification to carry out the present invention, which means that the scope of this invention is not limited to the embodiments in the specification.

In the following discussion, each transistor has a first terminal, a second terminal, and a control terminal. When the transistor is used as a switch, the first terminal and the second terminal of the transistor are the two terminals of the switch, and the control terminal controls the switch to be turned on (the transistor is turned on) or turned off (the transistor is turned off). For a Metal-Oxide-Semiconductor Field-Effect Transistor (MOSFET), the first terminal may be one of the source and the drain, the second terminal may be the other of the source and the drain, and the control terminal is the gate. For a bipolar junction transistor (BJT), the first terminal may be one of the collector and the emitter, the second terminal may be the other of the collector and the emitter, and the control terminal is the base.

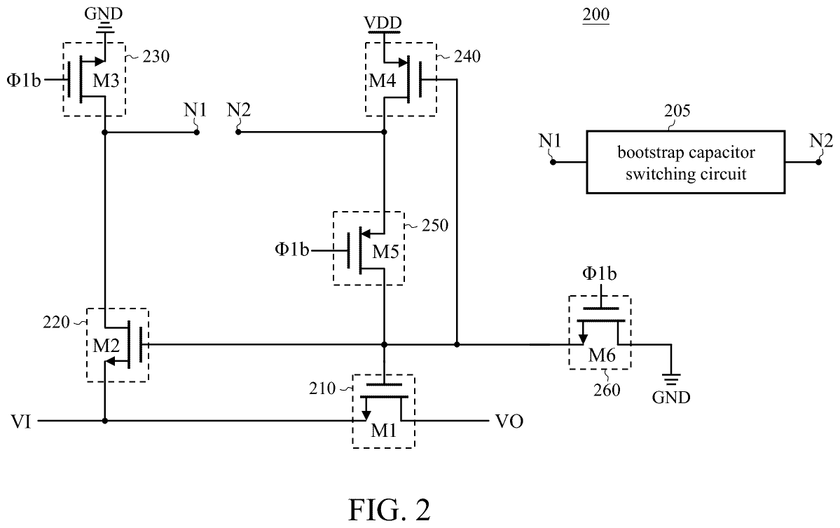

Reference is made to FIG. 2, which is the circuit diagram of a bootstrapped switch according to an embodiment of the present invention. The bootstrapped switch 200 includes a bootstrap capacitor switching circuit 205, a switch 210, a switch 220, a switch 230, a switch 240, a switch 250, and a switch 260. The input terminal and the output terminal of the bootstrapped switch 200 are respectively the input terminal VI and the output terminal VO.

The switch 210 is embodied by an NMOS transistor M1. One terminal (source) of the switch 210 is coupled or electrically connected to the input terminal VI; another terminal (drain) of the switch 210 is coupled or electrically connected to the output terminal VO; the control terminal of the switch 210 is the gate of the NMOS transistor M1.

The switch 220 is embodied by an NMOS transistor M2. One terminal (source) of the switch 220 is coupled or electrically connected to the input terminal VI; another terminal (drain) of the switch 220 is coupled or electrically connected to the node N1; the control terminal (gate) of the switch 220 is coupled or electrically connected to the control terminal of the switch 210.

The switch 230 is embodied by an NMOS transistor M3. One terminal (source) of the switch 230 is coupled or electrically connected to the reference voltage GND (e.g., ground); another terminal (drain) of the switch 230 is coupled or electrically connected to the node N1; the control terminal (gate) of the switch 230 receives a clock Φ1b.

The switch 240 is embodied by a P-channel Metal-Oxide-Semiconductor Field-Effect Transistor (hereinafter referred to as PMOS transistor) M4. One terminal (source) of the switch 240 is coupled or electrically connected to the reference voltage VDD (e.g., a power supply voltage); another terminal (drain) of the switch 240 is coupled or electrically connected to the node N2; the control terminal (gate) of the switch 240 is coupled or electrically connected to the control terminal of the switch 210.

The switch 250 is embodied by a PMOS transistor M5. One terminal (source) of the switch 250 is coupled or electrically connected to the node N2; another terminal (drain) of the switch 250 is coupled or electrically connected to the control terminal of the switch 210; the control terminal (gate) of the switch 250 receives the clock Φ1b.

The switch 260 is embodied by an NMOS transistor M6. One terminal (source) of the switch 260 is coupled or electrically connected to the control terminal of the switch 210; another terminal (drain) of the switch 260 is coupled or electrically connected to the reference voltage GND; the control terminal (gate) of the switch 260 receives the clock Φ1b.

The bootstrapped switch 200 operates according to the clock Φ1b. More specifically, when the clock Φ1b is at a first level (e.g., a high level), the switch 230, the switch 240, and the switch 260 are turned on, while the switch 210, the switch 220, and the switch 250 are turned off. When the clock Φ1b is at a second level (e.g., a low level), the switch 230, the switch 240, and the switch 260 are turned off, while the switch 210, the switch 220, and the switch 250 are turned on.

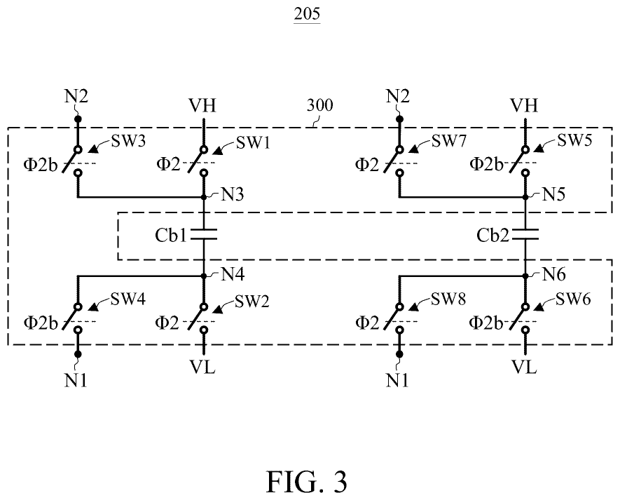

Reference is made to FIG. 3, which is the circuit diagram of the bootstrap capacitor switching circuit 205 according to an embodiment of the present invention. The bootstrap capacitor switching circuit 205 includes a capacitor Cb1, a capacitor Cb2, and a switch group 300. The two terminals of the capacitor Cb1 are a node N3 and a node N4, respectively. The two terminals of the capacitor Cb2 are a node N5 and a node N6, respectively. The switch group 300 includes a switch SW1, a switch SW2, a switch SW3, a switch SW4, a switch SW5, a switch SW6, a switch SW7, and a switch SW8. The switch group 300 couples or electrically connects the capacitor Cb1 or the capacitor Cb2 to the node N1 and the node N2 according to the clock Φ2 and/or the clock Φ2b.

One terminal of the switch SW1 is coupled or electrically connected to the node N3; another terminal of the switch SW1 is coupled or electrically connected to the voltage VH.

One terminal of the switch SW2 is coupled or electrically connected to the node N4; another terminal of the switch SW2 is coupled or electrically connected to the voltage VL.

One terminal of the switch SW3 is coupled or electrically connected to the node N2; another terminal of the switch SW3 is coupled or electrically connected to the node N3.

One terminal of the switch SW4 is coupled or electrically connected to the node N1; another terminal of the switch SW4 is coupled or electrically connected to the node N4.

One terminal of the switch SW5 is coupled or electrically connected to the node N5; another terminal of the switch SW5 is coupled or electrically connected to the voltage VH.

One terminal of the switch SW6 is coupled or electrically connected to the node N6; another terminal of the switch SW6 is coupled or electrically connected to the voltage VL.

One terminal of the switch SW7 is coupled or electrically connected to the node N2; another terminal of the switch SW7 is coupled or electrically connected to the node N5.

One terminal of the switch SW8 is coupled or electrically connected to the node N1; another terminal of the switch SW8 is coupled or electrically connected to the node N6.

The switches SW1 through SW8 operate according to the clock Φ2 and/or the clock Φ2b. More specifically, when the clock Φ2 is at the first level, the switch SW1, the switch SW2, the switch SW7, and the switch SW8 are turned on. When the clock Φ2 is at the second level, the switch SW1, the switch SW2, the switch SW7, and the switch SW8 are turned off. When the clock Φ2b is at the first level, the switch SW3, the switch SW4, the switch SW5, and the switch SW6 are turned on. When the clock Φ2b is at the second level, the switch SW3, the switch SW4, the switch SW5, and the switch SW6 are turned off.

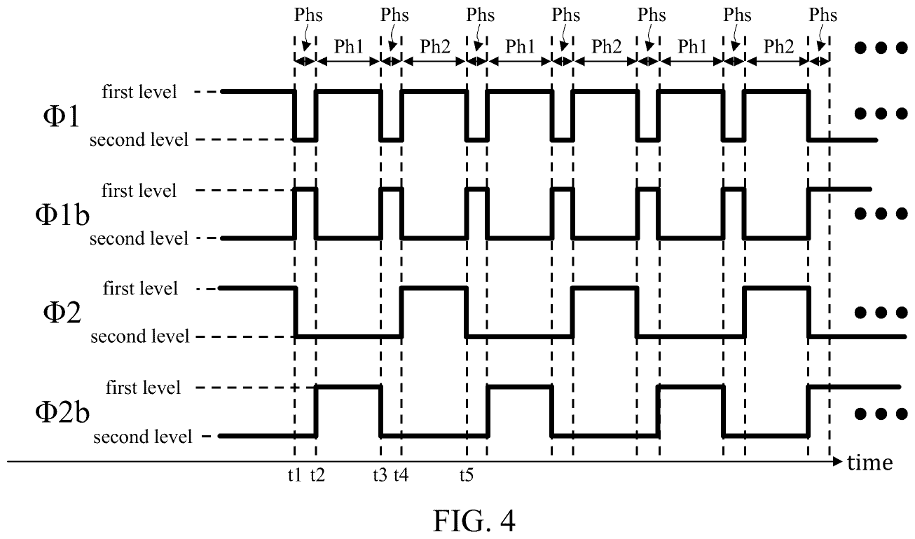

Reference is made to FIG. 4, which shows the waveform of multiple clocks according to an embodiment of the present invention. In the embodiment of FIG. 4, the clock Φ1 and the clock Φ1b are each other's inverted signal. More specifically, when the clock Φ1 is at the first level (the second level), the clock Φ1b is at the second level (the first level). When the clock Φ1 is at the first level, the bootstrapped switch 200 is turned on (i.e., the voltage at the output terminal VO is substantially equal to the voltage at the input terminal VI). When the clock Φ1 is at the second level, the bootstrapped switch 200 is turned off.

The clock Φ2 and the clock Φ2b are not at the first level at the same time. In other words, the capacitor Cb1 and the capacitor Cb2 are not electrically connected to the node N1 and the node N2 at the same time. More specifically, the node N3 and the node N5 are not electrically connected to the node N2 at the same time, and the node N4 and the node N6 are not electrically connected to the node N1 at the same time. When two nodes are electrically connected, the two nodes are substantially the same node; that is to say, there is no component between the two nodes.

The period of the clock Φ2 and the period of the clock Φ2b are substantially the same, and the periods of the clocks Φ2 and Φ2b are twice the periods of the clocks Φ1 and Φ1b.

Reference is made to both FIG. 3 and FIG. 4. During the phase Ph1 (the clock Φ1, the clock Φ1b, the clock Φ2, and the clock Φ2b are at the first level, the second level, the second level, and the first level, respectively), the two terminals of the capacitor Cb1 are respectively electrically connected to the node N1 and the node N2 (i.e., it is functioning as the bootstrap capacitor), while the two terminals of the capacitor Cb2 are respectively electrically connected to the voltage VH and the voltage VL (i.e., it is charging). During the phase Ph2 (the clock Φ1, the clock Φ1b, the clock Φ2, and the clock Φ2b are at the first level, the second level, the first level, and the second level, respectively), the two terminals of the capacitor Cb1 are respectively electrically connected to the voltage VH and the voltage VL (i.e., it is charging), while the two terminals of the capacitor Cb2 are respectively electrically connected to the node N1 and the node N2 (i.e., it is functioning as the bootstrap capacitor).

Continuing the previous paragraph, the capacitor Cb1 and the capacitor Cb2 alternately function as the bootstrap capacitor of the bootstrapped switch 200, that is, they are alternately coupled between the node N1 and the node N2. More specifically, during one period of the clock Φ2 or the clock Φ2b (e.g., between the time point t1 and the time point t5), the bootstrap capacitor of the bootstrapped switch 200 is sequentially the capacitor Cb1 (e.g., between the time point t2 and the time point t3) and the capacitor Cb2 (e.g., between the time point t4 and the time point t5). Therefore, the bootstrapped switch 200 can operate continuously without waiting for the bootstrap capacitor to charge, thereby significantly increasing the operating frequency of the bootstrapped switch 200.

As shown in FIG. 4, the bootstrapped switch 200 can be reset during the phase Phs (the clock Φ1, the clock Φ1b, the clock Φ2, and the clock Φ2b are respectively at the second level, the first level, the second level, and the second level) to improve the accuracy of the bootstrapped switch 200. Since resetting the bootstrapped switch 200 is well known to people having ordinary skill in the art, further elaboration is omitted for brevity.

In some embodiments, the length of the phase Phs may approach 0.

The voltage VH is different from the voltage VL. The voltage VH may or may not be equal to the reference voltage VDD. The voltage VL may or may not be equal to the reference voltage GND. In some embodiments, the voltage VH is equal to the reference voltage VDD, and the voltage VL is equal to the reference voltage GND, which simplifies the circuit design.

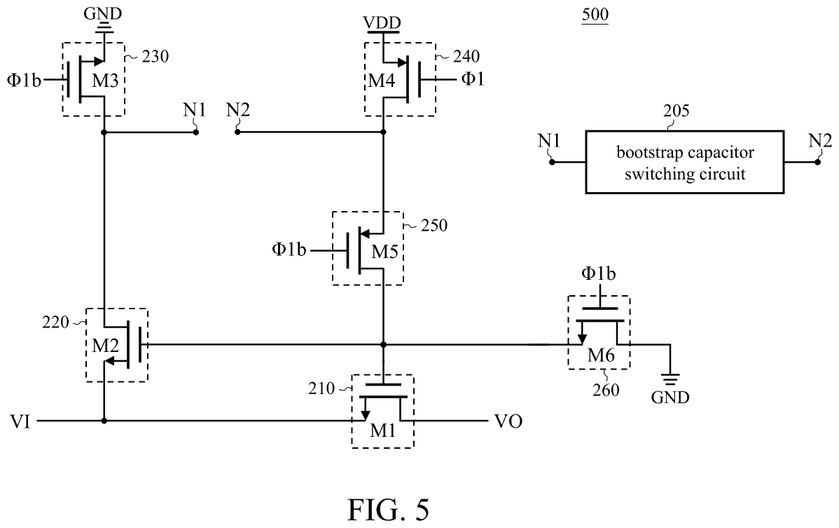

Reference is made to FIG. 5, which is the circuit diagram of the bootstrapped switch according to another embodiment of the present invention. The bootstrapped switch 500 is similar to the bootstrapped switch 200, except that in the embodiment of FIG. 5, the control terminal of the switch 240 is not coupled or electrically connected to the control terminal of the switch 210, but instead receives the clock Φ1.

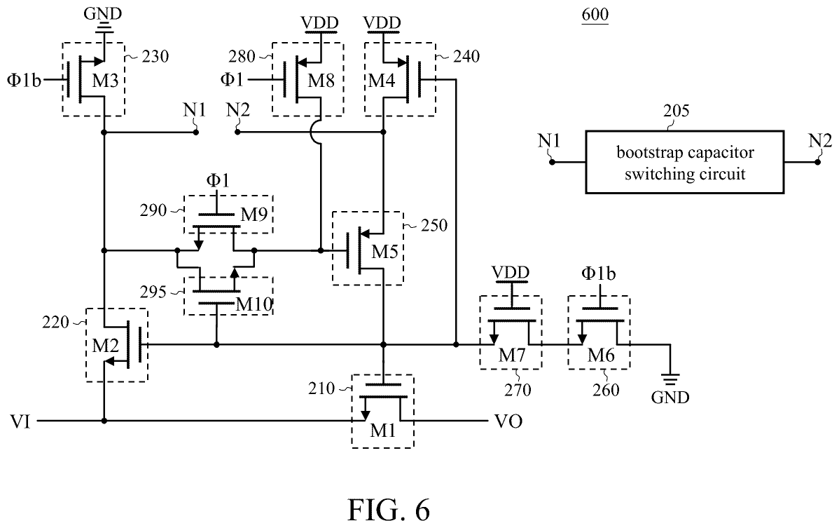

Reference is made to FIG. 6, which is the circuit diagram of the bootstrapped switch according to another embodiment of the present invention. The bootstrapped switch 600 is similar to the bootstrapped switch 200, except that the bootstrapped switch 600 further includes a switch 270, a switch 280, a switch 290, and a switch 295.

The switch 270 is embodied by an NMOS transistor M7. One terminal (source) of the switch 270 is coupled or electrically connected to the control terminal of the switch 210; another terminal (drain) of the switch 270 is coupled or electrically connected to the source of the NMOS transistor M6; the control terminal (gate) of the switch 270 is coupled or electrically connected to the reference voltage VDD.

The switch 280 is embodied by the PMOS transistor M8. One terminal (source) of the switch 280 is coupled or electrically connected to the reference voltage VDD; another terminal (drain) of the switch 280 is coupled or electrically connected to the control terminal of the switch 250; the control terminal (gate) of the switch 280 receives the clock Φ1.

The switch 290 is embodied by an NMOS transistor M9. One terminal of the switch 290 is coupled or electrically connected to the node N1 (source); another terminal (drain) of the switch 290 is coupled or electrically connected to the control terminal of the switch 250; the control terminal (gate) of the switch 290 receives the clock Φ1.

The switch 295 is embodied by an NMOS transistor M10. One terminal (source) of the switch 295 is coupled or electrically connected to the control terminal of the switch 250; another terminal (drain) of the switch 295 is coupled or electrically connected to the node N1; the control terminal (gate) of the switch 295 is coupled or electrically connected to the control terminal of the switch 210.

The switch 270, the switch 280, the switch 290, and the switch 295 serve as protective components for the bootstrapped switch 600. Since operating principles of those protective components are well known to people having ordinary skill in the art, further elaboration is omitted for brevity.

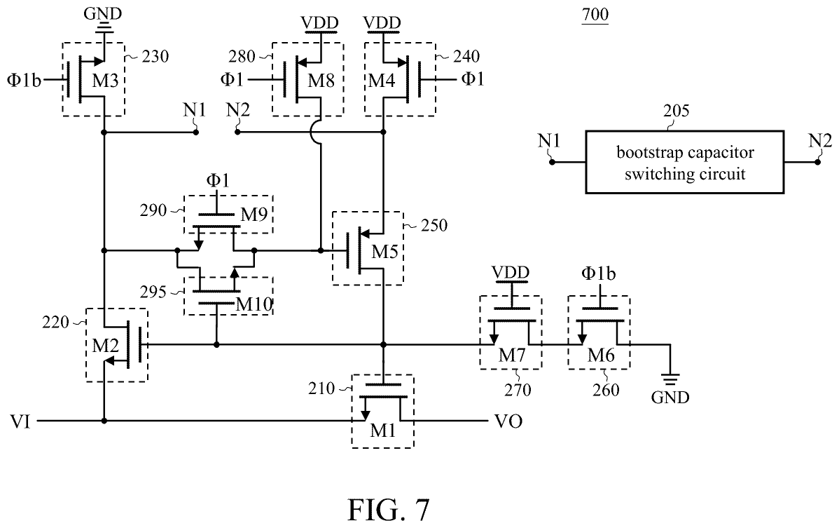

Reference is made to FIG. 7, which is the circuit diagram of the bootstrapped switch according to another embodiment of the present invention. The bootstrapped switch 700 is similar to the bootstrapped switch 600, except that in the embodiment of FIG. 7, the control terminal of the switch 240 is not coupled or electrically connected to the control terminal of the switch 210, but instead receives the clock Φ1.

In some embodiments, the bootstrapped switches 200, 500, 600, and 700 may omit the switches 230 and 240, because the capacitor Cb1 is coupled to the voltage VH and the voltage VL through the switches SW1 and SW2, respectively, and the capacitor Cb2 is coupled to the voltage VH and the voltage VL through the switches SW5 and SW6, respectively.

In an alternative embodiment, the PMOS transistors and the NMOS transistors in the aforementioned embodiments may be respectively replaced by NMOS transistors and PMOS transistors. People having ordinary skill in the art know how to correspondingly adjust the clock and the reference voltages to implement the aforementioned embodiments.

Note that the shape, size, and ratio of any element in the disclosed figures are exemplary for understanding, not for limiting the scope of this invention.

The aforementioned descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. A bootstrapped switch having an input terminal and an output terminal, the bootstrapped switch comprising:
a first switch having a first terminal, a second terminal, and a first control terminal, wherein the first terminal is coupled to the input terminal, and the second terminal is coupled to the output terminal;
a second switch having a third terminal, a fourth terminal, and a second control terminal, wherein the third terminal is coupled to the input terminal, the fourth terminal is coupled to a first node, and the second control terminal is coupled to the first control terminal;
a third switch having a fifth terminal, a sixth terminal, and a third control terminal, wherein the fifth terminal is coupled to a second node, the sixth terminal is coupled to the first control terminal, and the third control terminal receives a first clock;
a fourth switch having a seventh terminal, an eighth terminal, and a fourth control terminal, wherein the seventh terminal is coupled to the first control terminal, the eighth terminal is coupled to a first reference voltage, and the fourth control terminal receives the first clock; and
a bootstrap capacitor switching circuit coupled to the first node and the second node and comprising a first capacitor and a second capacitor;
wherein when the first capacitor is charging, the second capacitor is coupled between the first node and the second node, and when the second capacitor is charging, the first capacitor is coupled between the first node and the second node.

2. The bootstrapped switch of claim 1, wherein when the first clock is at a first level, the bootstrapped switch is turned off, and when the first clock is at a second level, the bootstrapped switch is turned on.

3. The bootstrapped switch of claim 2, wherein the first capacitor and the second capacitor are alternately coupled between the first node and the second node.

4. The bootstrapped switch of claim 1 further comprising:
a fifth switch having a ninth terminal, a tenth terminal, and a fifth control terminal, wherein the ninth terminal is coupled to the first control terminal, the tenth terminal is coupled to the seventh terminal, and the fifth control terminal is coupled to a second reference voltage;
a sixth switch having an eleventh terminal, a twelfth terminal, and a sixth control terminal, wherein the eleventh terminal is coupled to the second reference voltage, the twelfth terminal is coupled to the third control terminal, and the sixth control terminal receives a second clock;
a seventh switch having a thirteenth terminal, a fourteenth terminal, and a seventh control terminal, wherein the thirteenth terminal is coupled to the first node, the fourteenth terminal is coupled to the third control terminal, and the seventh control terminal receives the second clock; and
an eighth switch having a fifteenth terminal, a sixteenth terminal, and an eighth control terminal, wherein the fifteenth terminal is coupled to the third control terminal, the sixteenth terminal is coupled to the first node, and the eighth control terminal is coupled to the first control terminal.

5. The bootstrapped switch of claim 1, wherein two terminals of the first capacitor are respectively a third node and a fourth node, and two terminals of the second capacitor are respectively a fifth node and a sixth node, the bootstrap capacitor switching circuit further comprises:
a fifth switch coupled between the third node and a first voltage;
a sixth switch coupled between the fourth node and a second voltage;
a seventh switch coupled between the third node and the second node;
an eighth switch coupled between the fourth node and the first node;
a ninth switch coupled between the fifth node and the first voltage;
a tenth switch coupled between the sixth node and the second voltage;
an eleventh switch coupled between the fifth node and the second node; and
a twelfth switch coupled between the sixth node and the first node.

6. The bootstrapped switch of claim 5, wherein when a second clock is at a first level, the fifth switch, the sixth switch, the eleventh switch, and the twelfth switch are turned on; when the second clock is at a second level, the fifth switch, the sixth switch, the eleventh switch, and the twelfth switch are turned off; when a third clock is at the first level, the seventh switch, the eighth switch, the ninth switch, and the tenth switch are turned on; and when the third clock is at the second level, the seventh switch, the eighth switch, the ninth switch, and the tenth switch are turned off; the second clock and the third clock are not simultaneously at the first level.

7. The bootstrapped switch of claim 5 further comprising:
a thirteenth switch having a ninth terminal, a tenth terminal, and a fifth control terminal, wherein the ninth terminal is coupled to the first reference voltage, the tenth terminal is coupled to the first node, and the fifth control terminal receives the first clock; and
a fourteenth switch having an eleventh terminal, a twelfth terminal, and a sixth control terminal, wherein the eleventh terminal is coupled to a second reference voltage, the twelfth terminal is coupled to the second node, and the sixth control terminal is coupled to the first control terminal or receives a second clock.

8. The bootstrapped switch of claim 7, wherein the first voltage is not equal to the second voltage, the first voltage is substantially equal to the second reference voltage, and the second voltage is substantially equal to the first reference voltage.

9. The bootstrapped switch of claim 1, wherein the first switch, the second switch, and the fourth switch are N-channel metal-oxide-semiconductor field-effect transistors, and the third switch is a P-channel metal-oxide-semiconductor field-effect transistor.

10. The bootstrapped switch of claim 1, wherein the first switch, the second switch, the third switch, and the fourth switch are metal-oxide-semiconductor field-effect transistors, the first terminal, the third terminal, the fifth terminal, and the seventh terminal are sources of the metal-oxide-semiconductor field-effect transistors, and the second terminal, the fourth terminal, the sixth terminal, and the eighth terminal are drains of the metal-oxide-semiconductor field-effect transistors.

11. A bootstrapped switch having an input terminal and an output terminal, the bootstrapped switch comprising:
a first switch having a first terminal, a second terminal, and a first control terminal, wherein the first terminal is coupled to the input terminal, and the second terminal is coupled to the output terminal;
a second switch having a third terminal, a fourth terminal, and a second control terminal, wherein the third terminal is coupled to the input terminal, the fourth terminal is coupled to a first node, and the second control terminal is coupled to the first control terminal;
a third switch having a fifth terminal, a sixth terminal, and a third control terminal, wherein the fifth terminal is coupled to a second node, the sixth terminal is coupled to the first control terminal, and the third control terminal receives a first clock;
a fourth switch having a seventh terminal, an eighth terminal, and a fourth control terminal, wherein the seventh terminal is coupled to the first control terminal, the eighth terminal is coupled to a first reference voltage, and the fourth control terminal receives the first clock;
a first capacitor;
a second capacitor; and
a switch group coupled to the first capacitor and the second capacitor and configured to couple the first capacitor or the second capacitor to the first node and the second node according to a second clock and a third clock.

12. The bootstrapped switch of claim 11, wherein the first capacitor and the second capacitor are not simultaneously electrically connected to the first node and the second node.

13. The bootstrapped switch of claim 12, wherein the switch group alternately couples the first capacitor and the second capacitor between the first node and the second node.

14. The bootstrapped switch of claim 12, wherein two terminals of the first capacitor are respectively a third node and a fourth node; two terminals of the second capacitor are respectively a fifth node and a sixth node; when the second clock is at a level, the first capacitor charges, and the switch group electrically connects the fifth node and the sixth node to the second node and the first node, respectively; when the third clock is at the level, the second capacitor charges, and the switch group electrically connects the third node and the fourth node to the second node and the first node, respectively; the second clock and the third clock are not at the level simultaneously.

15. The bootstrapped switch of claim 11, wherein when the first clock is at a first level, the bootstrapped switch is turned off, and when the first clock is at a second level, the bootstrapped switch is turned on.

16. The bootstrapped switch of claim 11 further comprising:
a fifth switch having a ninth terminal, a tenth terminal, and a fifth control terminal, wherein the ninth terminal is coupled to the first control terminal, the tenth terminal is coupled to the seventh terminal, and the fifth control terminal is coupled to a second reference voltage;
a sixth switch having an eleventh terminal, a twelfth terminal, and a sixth control terminal, wherein the eleventh terminal is coupled to the second reference voltage, the twelfth terminal is coupled to the third control terminal, and the sixth control terminal receives a fourth clock;
a seventh switch having a thirteenth terminal, a fourteenth terminal, and a seventh control terminal, wherein the thirteenth terminal is coupled to the first node, the fourteenth terminal is coupled to the third control terminal, and the seventh control terminal receives the fourth clock; and
an eighth switch having a fifteenth terminal, a sixteenth terminal, and an eighth control terminal, wherein the fifteenth terminal is coupled to the third control terminal, the sixteenth terminal is coupled to the first node, and the eighth control terminal is coupled to the first control terminal.

17. The bootstrapped switch of claim 11, wherein two terminals of the first capacitor are respectively a third node and a fourth node, two terminals of the second capacitor are respectively a fifth node and a sixth node, the switch group comprises:
a fifth switch coupled between the third node and a first voltage;
a sixth switch coupled between the fourth node and a second voltage;
a seventh switch coupled between the third node and the second node;
an eighth switch coupled between the fourth node and the first node;
a ninth switch coupled between the fifth node and the first voltage;
a tenth switch coupled between the sixth node and the second voltage;
an eleventh switch coupled between the fifth node and the second node; and
a twelfth switch coupled between the sixth node and the first node.

18. The bootstrapped switch of claim 17, wherein when the second clock is at a first level, the fifth switch, the sixth switch, the eleventh switch, and the twelfth switch are turned on; when the second clock is at a second level, the fifth switch, the sixth switch, the eleventh switch, and the twelfth switch are turned off; when the third clock is at the first level, the seventh switch, the eighth switch, the ninth switch, and the tenth switch are turned on; and when the third clock is at the second level, the seventh switch, the eighth switch, the ninth switch, and the tenth switch are turned off; the second clock and the third clock are not simultaneously at the first level.

19. The bootstrapped switch of claim 17 further comprising:
a thirteenth switch having a ninth terminal, a tenth terminal, and a fifth control terminal, wherein the ninth terminal is coupled to the first reference voltage, the tenth terminal is coupled to the first node, and the fifth control terminal receives the first clock; and
a fourteenth switch having an eleventh terminal, a twelfth terminal, and a sixth control terminal, wherein the eleventh terminal is coupled to a second reference voltage, the twelfth terminal is coupled to the second node, and the sixth control terminal is coupled to the first control terminal or receives a fourth clock.

20. The bootstrapped switch of claim 19, wherein the first voltage is not equal to the second voltage, the first voltage is substantially equal to the second reference voltage, and the second voltage is substantially equal to the first reference voltage.
